(19) United States
(12) Patent Application Publication
(10) Pub. No.: US 2026/0323229 A1
(43) Pub. Date: Oct. 15, 2026

(54) LOUDSPEAKER LOAD DIAGNOSIS METHOD, SYSTEM, DEVICE AND MEDIUM

(71) Applicant: SUZHOU LINK-IC CO., LTD., Suzhou (CN)

(72) Inventors: Xing WAN, Suzhou (CN); Wenjie FAN, Suzhou (CN)

(73) Assignee: SUZHOU LINK-IC CO., LTD., Suzhou, JS (CN)

(21) Appl. No.: 18/996,727

(22) PCT Filed: Nov. 8, 2024
(86) PCT No.: PCT/CN2024/130718

§ 371 Date: Jan. 17, 2025

(30) Foreign Application Priority Data
Dec. 25, 2023 (CN) 202311799478.0

(51) Int. Cl. H04R 29/00; G01R 31/28

(52) U.S. Cl. CPC H04R 29/001; G01R 31/2825

(57) ABSTRACT

The present invention provides a loudspeaker load diagnosis method, system, device and medium. The method includes by obtaining voltage and current data output by a first terminal and a second terminal of an amplifier, performing filtering processing on the voltage and current data to obtain feature voltage and current data, obtaining feature energy data of the feature voltage and current data within a pre-set observation time window, only when the feature energy data is greater than the first threshold, judging that the voltage and current data is reliable, and according to the feature voltage and current data, calculating a measured resistance value of the loudspeaker, and respectively comparing the measured resistance value with a lower threshold and an upper threshold to detect an operating state of a load of the loudspeaker; otherwise, the voltage and current data is judged to be unreliable, and resetting the obtained voltage and current data; thus, it is possible to detect whether there is a short-circuit fault or an open-circuit fault in the loudspeaker load without adding an additional output signal, while taking into account the flexibility and intuition in the threshold configuration.

### TECHNICAL FIELD

The present invention relates to the technical field of loudspeakers, and more particularly to a loudspeaker load diagnosis method, system, device and medium.

### BACKGROUND ART

In the existing acoustic products, if the product collides or the product ages, the connection between a loudspeaker (or load) and the power amplifier of the previous stage may be abnormal. In this case, if the product continues to be used, there may be risks of abnormal increase in power consumption and no sound from the loudspeaker.

At present, the commonly used methods for loudspeaker load diagnosis are: the loudspeaker load is monitored for short-circuit faults or open-circuit faults by detecting the resistance of the load or monitoring the resistance on the side. For the existing detection in practical implementations, a tailored signal outside the audible range of the human ear can be output to assist in detection, or the current range can be predicted from the input audio signal, and whether a short-circuit fault or open-circuit fault exists is judged by comparing the measured current with the predicted current.

There are the following problems from the above:
(1) Since the common sound frequency response is 20-20 KHz, the tailored signal outside the audible range of human ear may generate harmonic distortion, so that the human ear can hear a frequency multiplication component of the tailored signal, affecting a playing effect;
(2) It is necessary to add additional management and control measures in the product production process, which affects the product yield, and playing the tailored signals will increase additional power consumption;
(3) Because variations in current can be affected by a number of factors in the circuit, there is less flexibility and intuition in setting the thresholds for comparing the measured current to the predicted current, which increases the cost of debugging.

Therefore, how to detect whether there is a short-circuit fault or an open-circuit fault in a loudspeaker load without adding an additional output signal, and taking into account the flexibility and intuition in threshold configuration has become a technical problem that needs to be solved urgently in the industry.

### SUMMARY OF THE INVENTION

The present invention provides a loudspeaker load diagnosis method, system, device, and medium to solve the problem of how to detect whether there is a short-circuit fault or an open-circuit fault in a loudspeaker load without adding an additional output signal, and taking into account the flexibility and intuition in threshold configuration.

According to a first aspect of the present invention, a loudspeaker load diagnosis method is provided, where a first terminal and a second terminal of the loudspeaker are respectively coupled to a first terminal and a second terminal of an amplifier: the method including:
obtaining voltage and current data output by the first terminal and the second terminal of the amplifier;
performing filtering processing on the voltage and current data to obtain feature voltage and current data;
calculating a measured resistance value of the loudspeaker based on the feature voltage and current data;
obtaining feature energy data of the feature voltage and current data within a pre-set observation time window; and
judging whether the voltage and current data is reliable based on the feature energy data; where the voltage and current data is judged to be reliable only if the feature energy data is greater than a first threshold; otherwise, the voltage and current data is judged to be unreliable;
where
if the voltage and current data is reliable, performing the following steps:
comparing the measured resistance value with a lower threshold and an upper threshold respectively, detecting an operating state of a loudspeaker load, and outputting a detection result;
if the voltage and current data is unreliable, performing the following steps:
resetting the obtained voltage and current data.

Alternatively, the voltage and current data includes a first voltage and a first current output by the first terminal of the amplifier, and a second voltage and a second current output by the second terminal of the amplifier; the feature voltage and current data includes a first feature voltage corresponding to the first voltage, a first feature current corresponding to the first current, a second feature voltage corresponding to the second voltage and a second feature current corresponding to the second current;
obtaining feature energy data of the feature voltage and current data within a pre-set observation time window, specifically including:
extracting amplitude, energy or decibels of the first feature voltage, the first feature current, the second feature voltage and the second feature current within the pre-set observation time window.

Alternatively, a formula for calculating a measured resistance value of the loudspeaker based on the feature voltage and current data is as follows:

$${R}_{estimate} = \frac{\sum \vert {V}_{feature} \vert}{\sum \vert {I}_{feature} \vert}$$

where Rₑₛₜᵢₘₐₜₑ is a measured resistance value of the loudspeaker, V_{feature} is a differential voltage value, and I_{feature} is a current feature value; where the differential voltage value is a difference between the first feature voltage and the second feature voltage, and the current feature value is a smaller value between the first feature current and the second feature current.

Alternatively, a formula for calculating a measured resistance value of the loudspeaker based on the feature voltage and current data is as follows:

$${R}_{estimate} = \frac{\sqrt{\sum {( {V}_{feature} )}^{2}}}{\sqrt{\sum {( {I}_{feature} )}^{2}}}$$

where Rₑₛₜᵢₘₐₜₑ is a measured resistance value of the loudspeaker, V_{feature} is a differential voltage value, and I_{feature} is a current feature value; where the differential voltage value is a difference between the first feature voltage and the second feature voltage, and the current feature value is a smaller value between the first feature current and the second feature current.

Alternatively, a formula for calculating a measured resistance value of the loudspeaker based on the feature voltage and current data is as follows:

$${R}_{estimate} = db 2 linear ( linear 2 db ( \sum ( {V}_{feature} ) ) - linear 2 db ( \sum {( {I}_{feature} )}^{2} ) )$$

where Rₑₛₜᵢₘₐₜₑ is a measured resistance value of the loudspeaker, V_{feature} is a differential voltage value, and I_{feature} is a current feature value; where the differential voltage value is a difference between the first feature voltage and the second feature voltage, and the current feature value is a smaller value between the first feature current and the second feature current.

Alternatively, judging whether the voltage and current data is reliable based on the feature energy data, specifically including:
within the pre-set observation time window, if the time when the first feature voltage and the second feature voltage exceed a set voltage value exceeds the first threshold, judging that the voltage and current data is reliable;
otherwise, the voltage and current data is judged to be unreliable.

Alternatively, the operating state includes a short-circuit state, an open-circuit state and a normal operating state;
comparing the measured resistance value with a lower threshold and an upper threshold respectively, detecting an operating state of a loudspeaker load, and outputting a detection result, specifically including:
comparing the measured resistance value with a lower threshold and an upper threshold respectively, and if the measured resistance value is less than the lower threshold, judging that the loudspeaker is in a short-circuit state;
if the measured resistance value is greater than the lower threshold and less than the upper threshold, judging that the loudspeaker is in a normal operating state;
if the measured resistance value is greater than the upper threshold, judging that the loudspeaker is in an open-circuit state.

According to a second aspect of the present invention, a loudspeaker load diagnosis system is provided, including:
an amplifier;
a loudspeaker having a first terminal and a second terminal respectively coupled to a first terminal and a second terminal of an amplifier;
a voltage and current data acquisition module configured to obtain voltage and current data output by the first terminal and the second terminal of the amplifier;
a feature voltage and current data acquisition module configured to perform filtering processing on the voltage and current data to obtain feature voltage and current data;
a measured resistance value acquisition module configured to calculate a measured resistance value of the loudspeaker based on the feature voltage and current data;
a feature energy data acquisition module configured to obtain feature energy data of the feature voltage and current data within a pre-set observation time window;
a data reliability judgment module configured to judge whether the voltage and current data is reliable based on the feature energy data; where the voltage and current data is judged to be reliable only if the feature energy data is greater than a first threshold; otherwise, the voltage and current data is judged to be unreliable;
a detection module configured to,
if the voltage and current data is reliable, perform the following steps:
compare the measured resistance value with a lower threshold and an upper threshold respectively, detect an operating state of a loudspeaker load, and output a detection result;
if the voltage and current data is unreliable, perform the following steps:
reset the obtained voltage and current data.

Alternatively, the system further includes a DAC module;
where an input end of the DAC module receives an audio digital signal, and an output end thereof is coupled to an input end of the amplifier to output a voltage control signal, the voltage control signal including voltage data output by the first terminal and the second terminal of the amplifier.

Alternatively, the voltage and current data acquisition module is configured to, obtain current data output by the first terminal and second terminal of the amplifier and obtaining voltage data output by the first terminal and second terminal of the amplifier based on the voltage control signal.

According to a third aspect of the present invention, an electronic device is provided, including a memory, a processor and a program stored on the memory and executable on the processor, wherein the processor, when executing the program, implements the steps of the method of any one of the first aspect of the present invention.

According to a fourth aspect of the present invention, a computer readable storage medium having stored thereon a computer program which, when executed by a processor, performs the steps in the method of any one of the first aspects of the present invention is provided.

The present invention provides a loudspeaker load diagnosis method, system, device and medium, the method includes by obtaining voltage and current data output by a first terminal and a second terminal of an amplifier, performing filtering processing on the voltage and current data to obtain feature voltage and current data, obtaining feature energy data of the feature voltage and current data within a pre-set observation time window, only when the feature energy data is greater than the first threshold, judging that the voltage and current data is reliable, and according to the feature voltage and current data, calculating a measured resistance value of the loudspeaker, and respectively comparing the measured resistance value with a lower threshold and an upper threshold to detect an operating state of a load of the loudspeaker; otherwise, the voltage and current data is judged to be unreliable, and resetting the obtained voltage and current data; thus, it is possible to detect whether there is a short-circuit fault or an open-circuit fault in the loudspeaker load without adding an additional output signal, while taking into account the flexibility and intuition in the threshold configuration.

### BRIEF DESCRIPTION OF THE DRAWINGS

In order to explain the technical solutions in the embodiments or the prior art of the present invention more clearly, a brief description will be given below referring to the accompanying drawings which are used in the description of the embodiments or the prior art, and it is obvious that the drawings in the description below are merely some embodiments of the present invention, and it would have been obvious for a person skilled in the art to obtain other drawings according to these drawings without involving any inventive effort.

FIG. 1 is a schematic diagram showing a connection construction of a loudspeaker load and an amplifier according to an embodiment of the present invention;

FIG. 2 is a schematic flow diagram showing a loudspeaker load diagnosis method according to an embodiment of the present invention;

FIG. 3 is a waveform diagram showing an operation effect of a loudspeaker load diagnosis method shown in FIG. 2;

FIG. 4 is a first block diagram showing a loudspeaker load diagnosis system according to an embodiment of the present invention;

FIG. 5 is a second block diagram showing a loudspeaker load diagnosis system according to an embodiment of the present invention;

FIG. 6 is a third block diagram showing a loudspeaker load diagnosis system according to an embodiment of the present invention; and

FIG. 7 is a schematic construction diagram showing an exemplary electronic device according to an embodiment of the present invention.

### DESCRIPTION OF REFERENCE NUMERALS

1—Amplifier;
2—Loudspeaker;
3—Voltage and current data acquisition module;
4—Feature voltage and current data acquisition module;
5—Measured resistance value acquisition module;
6—Feature energy data acquisition module;
7—Data reliability judgment module;
8—Detection module
9—
10
31—P-terminal current detector;
32—N-terminal current detector;
33—Voltage detector;
41—P-terminal LC filter;
42—N-terminal LC filter;
101—Processor;
103—Bus;
102—Memory.

### DETAILED DESCRIPTION OF THE INVENTION

The embodiments of the present invention will now be described more fully hereinafter referring to the accompanying drawings, in which embodiments of the present invention are shown. It is to be understood that the embodiments described are only a few, but not all embodiments of the present invention. Based on the embodiments of the present invention, all other embodiments obtained by a person of ordinary skill in the art without inventive effort fall within the scope of the present invention.

The terms “first”, “second”, “third”, “fourth”, and the like in the description and in the claims of the present invention and in the above-described figures, if any, are used for distinguishing between similar objects and not necessarily for describing a particular sequential or chronological order. It is to be understood that the data so used are interchangeable under appropriate circumstances such that the embodiments of the present invention described herein are capable of operation in sequences other than those illustrated or otherwise described herein. Further, the terms “include” and “have”, as well as any variations thereof, are intended to cover a non-exclusive inclusion, such that a process, method, system, product, or device that includes a list of steps or elements is not necessarily limited to those steps or elements expressly listed, but may include other steps or elements not expressly listed or inherent to such process, method, system, product, or device.

Hereinafter, embodiments of the present invention will be described in detail referring to specific examples. The following specific embodiments may be combined with one another, and the same or similar concepts or processes may not be repeated in some embodiments.

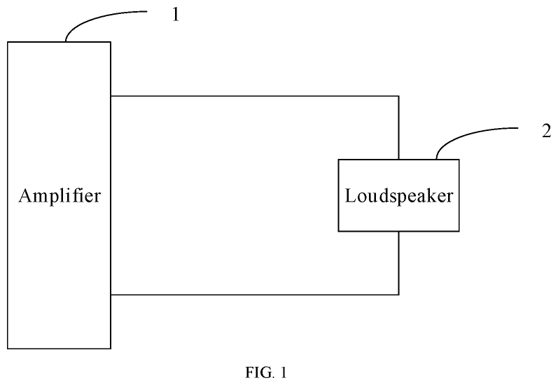

An embodiment of the present invention provides a loudspeaker load diagnosis method. Referring to FIG. 1, where a first terminal and a second terminal of the loudspeaker 2 are respectively coupled to a first terminal and a second terminal of an amplifier 1, the method including:
voltage and current data output by the first terminal and the second terminal of the amplifier 1 is obtained;
filtering processing is performed on the voltage and current data to obtain feature voltage and current data;
a measured resistance value of the loudspeaker 2 is calculated based on the feature voltage and current data;
feature energy data of the feature voltage and current data within a pre-set observation time window is obtained; and
whether the voltage and current data is reliable based on the feature energy data is judged; where the voltage and current data is judged to be reliable only if the feature energy data is greater than a first threshold; otherwise, it is judged that the voltage and current data is unreliable;
where
if the voltage and current data is reliable, the following steps are performed:
comparing the measured resistance value with a lower threshold and an upper threshold respectively, detecting an operating state of a loudspeaker 2 load, and outputting a detection result;
if the voltage and current data is unreliable, performing the following steps:
resetting the obtained voltage and current data.

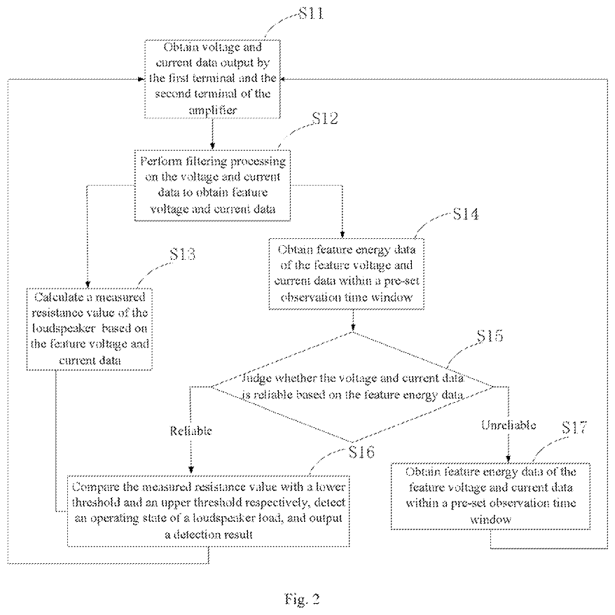

As a specific embodiment, referring to FIG. 2, in practice, using a loudspeaker load diagnosis method provided by an embodiment of the present invention to detect an operating state of a loudspeaker 2 load includes the following steps:
S11 Obtain voltage and current data output by the first terminal and the second terminal of the amplifier 1.

The voltage and current data includes a first voltage and a first current output by a first terminal of the amplifier 1, and a second voltage and a second current output by a second terminal of the amplifier 1;
S12 Perform filtering processing on the voltage and current data to obtain feature voltage and current data, and proceed to S13 and S14;
In one embodiment, the feature voltage and current data includes a first feature voltage corresponding to the first voltage, a first feature current corresponding to the first current, a second feature voltage corresponding to the second voltage and a second feature current corresponding to the second current;
the filtering processing includes noise filtering processing and feature extraction processing;
the noise filtering processing is used for filtering out high-frequency noise in the feature voltage and current data so as to prevent the noise from affecting the calculation result;
the feature extraction processing is used for extracting a signal of a particular frequency band in the feature voltage and current data as the feature voltage and current data. In one example, a 100 Hz-4 kHz signal may be selected based on the dominant energy composition of the music, although a suitable frequency band may be selected based on the type of signal desired to be output by the loudspeaker.
S13 Calculate a measured resistance value of the loudspeaker 2 based on the feature voltage and current data;
in one embodiment, for example, an average resistance value of the loudspeaker 2 in a pre-set observation time window can be obtained as a measured resistance value of the loudspeaker 2;
in a particular embodiment, the formula for calculating the measured resistance value of the loudspeaker 2 on the basis of the feature voltage and current data may for example be:

$${R}_{estimate} = \frac{\sum \vert {V}_{feature} \vert}{\sum \vert {I}_{feature} \vert}$$

In another embodiment, the formula for calculating the measured resistance value of the loudspeaker 2 based on the feature voltage and current data may also be:

$${R}_{estimate} = \frac{\sqrt{\sum {( {V}_{feature} )}^{2}}}{\sqrt{\sum {( {I}_{feature} )}^{2}}}$$

If the measured resistance value of the loudspeaker 2 is calculated using decibels, in a particular embodiment, the formula for calculating the measured resistance value of the loudspeaker 2 based on the feature voltage and current data may also be:

$${R}_{estimate} = db 2 linear ( linear 2 db ( \sum ( {V}_{feature} ) ) - linear 2 db ( \sum {( {I}_{feature} )}^{2} ) )$$

where Rₑₛₜᵢₘₐₜₑ is a measured resistance value of the loudspeaker, V_{feature} is a differential voltage value, and I_{feature} is a current feature value; where the differential voltage value is a difference between the first feature voltage and the second feature voltage, and the current feature value is a smaller value between the first feature current and the second feature current.

It should be understood that the present invention is not limited to the specific way of calculating the measured resistance value of the loudspeaker 2, but may be obtained by other formulas for obtaining an average value, and a person skilled in the art may select a suitable formula according to needs.
S14 Obtain feature energy data of the feature voltage and current data within a pre-set observation time window;
specifically, amplitude, energy or decibels of the first feature voltage, the first feature current, the second feature voltage and the second feature current within the pre-set observation time window can be extracted;

Of course, a person skilled in the art would have been able to select different features of the first feature voltage, the first feature current, the second feature voltage and the second feature current as the feature energy data according to resource occupation and accuracy requirements in an actual scenario.
S15 Judge whether the voltage and current data is reliable based on the feature energy data; if the voltage and current data is reliable, the process proceeds to S16; otherwise, proceeding to S17;
Specifically, within the pre-set observation time window, if the time when the first feature voltage and the second feature voltage exceed a set voltage value exceeds the first threshold, it is judged that the voltage and current data is reliable, proceeding to S16;
Otherwise, it is judged that the voltage and current data is unreliable, proceeding to S17.
S16 Compare the measured resistance value with a lower threshold and an upper threshold respectively, detect an operating state of a loudspeaker 2 load, and output a detection result, and returning to S11;
Specifically, the operating state includes a short-circuit state, an open-circuit state and a normal operating state;
if the measured resistance value is less than the lower threshold, it is judged that the loudspeaker 2 is in a short-circuit state;
if the measured resistance value is greater than the lower threshold and less than the upper threshold, it is judged that the loudspeaker 2 is in a normal operating state;
if the measured resistance value is greater than the upper threshold, it is judged that the loudspeaker 2 is in an open-circuit state.

In a preferred embodiment, S16 further includes:

And if the operating state of the loudspeaker 2 is in a short-circuit state or an open-circuit state, the amplifier 1 is controlled to stop outputting voltage and current to the loudspeaker 2.
S17 Reset the obtained voltage and current data and return to S11.

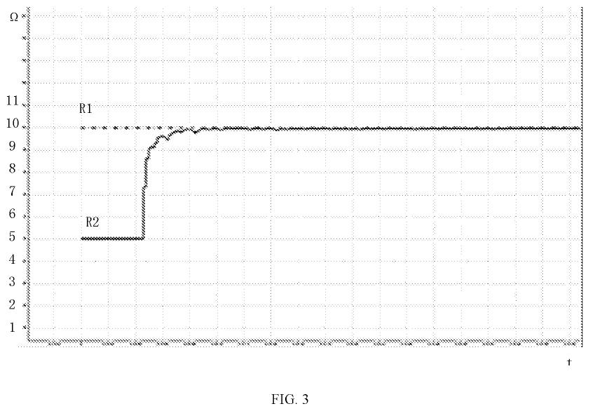

In order to better embody the operation effect of the present invention, the operation effect of the loudspeaker load diagnosis method of the present invention will now be described referring to the waveform diagram shown in FIG. 3.
R1 can be understood as the actual resistance value of the loudspeaker 2;
R2 can be understood as the calculated measured resistance value of the loudspeaker 2.

Referring to FIG. 3, as the length of time in a pre-set observation time window increases, the calculated measured resistance value of the loudspeaker 2 will be closer to the actual resistance value of the loudspeaker 2, and the current operating state of the loudspeaker 2 can be obtained by comparing the measured resistance value with a lower threshold and an upper threshold respectively.

In summary, the present invention can reduce resource and power consumption overhead by detecting whether there is a short-circuit fault or an open-circuit fault in the load of the loudspeaker 2 without adding an additional output signal, and since the present invention is based on the measured resistance value of the loudspeaker 2 as a judgment basis, it is highly flexible and intuitive in threshold configuration.

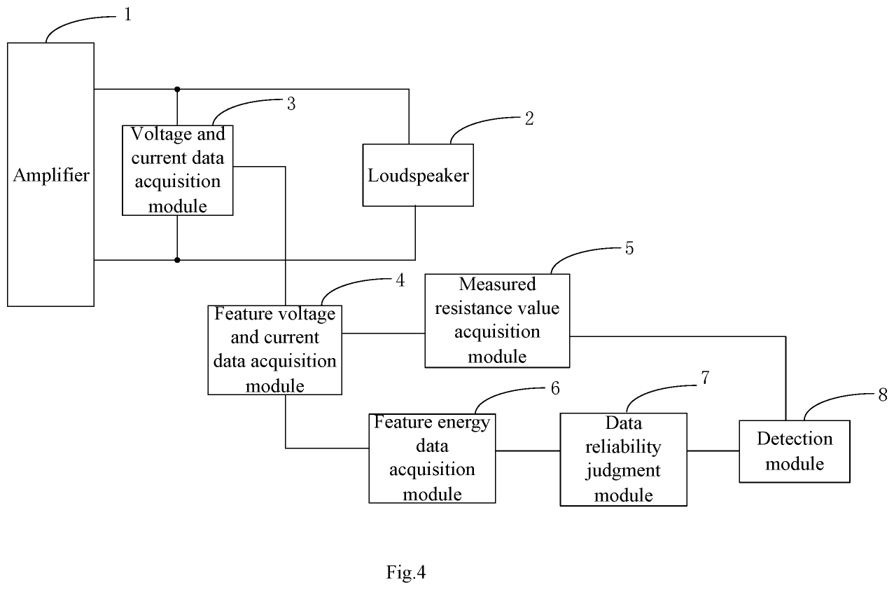

Further, referring to FIG. 4, an embodiment of the present invention also provides a loudspeaker load diagnosis system including:
an amplifier 1;
a loudspeaker 2 having a first terminal and a second terminal respectively coupled to a first terminal and a second terminal of an amplifier 1;
a voltage and current data acquisition module 3 configured to obtain voltage and current data output by the first terminal and the second terminal of the amplifier 1;
a feature voltage and current data acquisition module 4 configured to perform filtering processing on the voltage and current data to obtain feature voltage and current data;
a measured resistance value acquisition module 5 configured to calculate a measured resistance value of the loudspeaker 2 based on the feature voltage and current data;
a feature energy data acquisition module 6 configured to obtain feature energy data of the feature voltage and current data within a pre-set observation time window;
a data reliability judgment module 7 configured to judge whether the voltage and current data is reliable based on the feature energy data; where the voltage and current data is judged to be reliable only if the feature energy data is greater than a first threshold; otherwise, the voltage and current data is judged to be unreliable;
a detection module 8 configured to,
if the voltage and current data is reliable, perform the following steps:
compare the measured resistance value with a lower threshold and an upper threshold respectively, detect an operating state of a loudspeaker 2 load, and output a detection result;
if the voltage and current data is unreliable, perform the following steps:
reset the obtained voltage and current data.

In one example, the amplifier 1 may be, for example, a class D amplifier 1, of course, a class S amplifier 1, etc. to which the present invention is not limited, and a person skilled in the art may select a suitable type of amplifier 1.

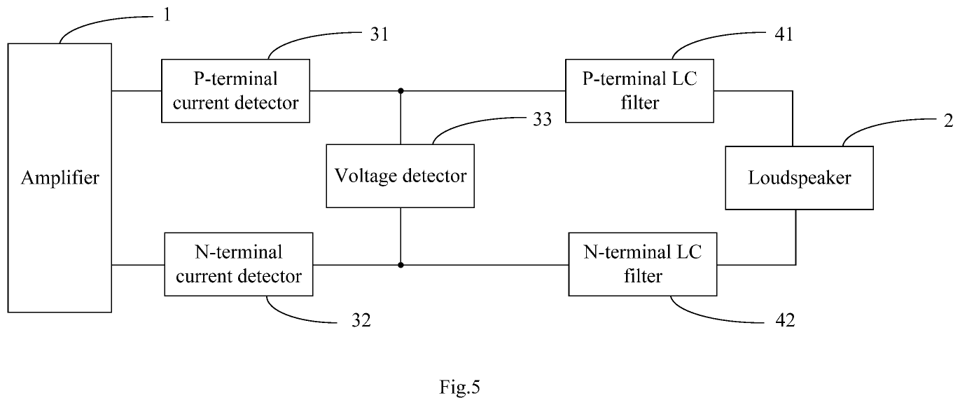

In a specific embodiment, referring to FIG. 5, the voltage and current data acquisition module 3 includes a P-terminal current detector 31, an N-terminal current detector 32 and a voltage detector 33; the feature voltage and current data 4 acquisition module includes a P-terminal LC filter 41 and an N-terminal LC filter 42;
a first terminal of the amplifier 1 is sequentially coupled to a first terminal of the loudspeaker 2 via the P-terminal current detector 31 and the P-terminal LC filter 41;
a second terminal of the amplifier 1 is sequentially coupled to a second terminal of the loudspeaker 2 via the N-terminal current detector 32 and the N-terminal LC filter 42;
the voltage detector 33 is arranged to detect a voltage between a first terminal and a second terminal of the amplifier 1.
The voltage data output by the first terminal and the second terminal of the amplifier 1 obtained in this way can also be considered as a real voltage value.

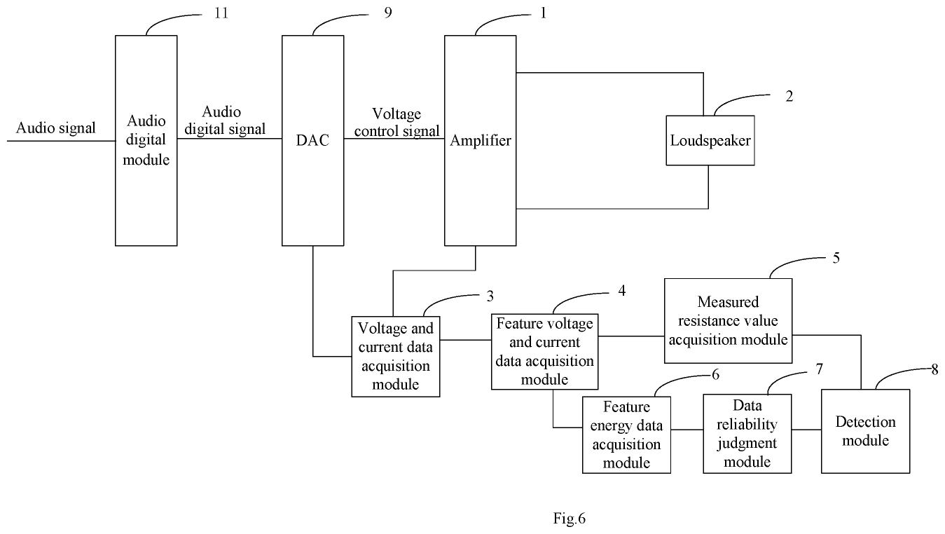

To conserve resources, in other specific embodiments, referring to FIG. 6, the loudspeaker load diagnosis system further includes a DAC module 9;
where an input end of the DAC module 9 receives an audio digital signal, and an output end thereof is coupled to an input end of the amplifier 1 to output a voltage control signal, the voltage control signal including voltage data output by the first terminal and the second terminal of the amplifier 1.

In this case, the voltage and current data acquisition module 3 may also be configured to obtain current data output by the first terminal and second terminal of the amplifier 1 and obtaining voltage data output by the first terminal and second terminal of the amplifier 1 based on the voltage control signal.

The voltage data output by the first terminal and the second terminal of the amplifier 1 obtained in this way can be considered as an estimated voltage value, and in practical implementations, the estimated voltage value has a small difference from the formal voltage value and can replace each other.

In the example shown in FIG. 6, the loudspeaker load diagnosis system further includes an audio digital module 11 for receiving an audio signal output by a main control chip (not shown in the figure) and converting same into the audio digital signal which is further used for controlling functions of the loudspeaker 2, such as an equalizer EQ, a sample rate converter SRC, a SDM, etc.

In a practical implementation, in one embodiment, the loudspeaker load diagnosis system further includes a feedback module;

the feedback module is configured to receive the detection result and feedback the current working state of the loudspeaker 2 to the main control chip.

The feedback module may for example include a number of registers by means of which the current operating state of the loudspeaker 2 is fed back. It should be understood that the present invention is not limited to the specific implementation of the feedback module.

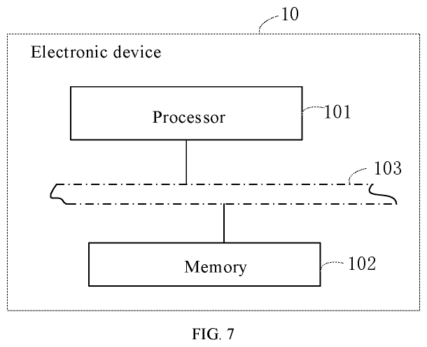

In addition, embodiments of the present invention provide an electronic device. Referring to FIG. 7, the electronic device 10 includes a memory 102, a processor 101, and a program stored on the memory 102 and executable on the processor 101 to perform the steps of the loudspeaker load diagnosis method of the foregoing aspect of the present invention. The processor 101 can communicate with the memory 102 over bus 103.

Further, embodiments of the present invention provide a computer-readable storage medium having stored thereon a computer program which, when executed by a processor, implements the steps of the loudspeaker load diagnosis method in the aforementioned aspect of the present invention.

The system, apparatus, module or unit illustrated in the above embodiments may be embodied in a computer chip or entity, or in a product having certain function. A typical implementation device is a computer, which may take the form of a personal computer, laptop computer, cellular telephone, camera phone, smart phone, personal digital assistant, media player, navigation device, e-mail transceiving device, game console, tablet computer, wearable device, or a combination of any of these.

In a typical configuration, the computer includes one or more CPU, an input/output interface, a network interface, and a memory.

The memory may include forms of non-persistent memory, random access memory (RAM), and/or non-volatile memory such as read only memory (ROM) or flash memory (flash RAM) in a computer readable medium. The memory is an example of a computer-readable medium.

Computer-readable media, including both permanent and non-permanent, removable and non-removable media, can implement information storage by any method or technology. The information may be computer readable instructions, data structures, modules of a program, or other data. Examples of storage media for computers include, but are not limited to, phase change memory (PRAM), static random access memory (SRAM), dynamic random access memory (DRAM), other types of random access memory (RAM), read only memory (ROM), electrically erasable programmable read only memory (EEPROM), flash memory or other memory technologies, compact disk read only memory (CD-ROM), digital versatile disks (DVD) or other optical storage, magnetic cassettes, magnetic disk storage, quantum memory, graphene-based storage media or other magnetic storage devices or any other non-transmission media may be used to store information that may be accessed by a computing device.

In summary, according to the present embodiment of the present invention, the method includes by obtaining voltage and current data output by a first terminal and a second terminal of an amplifier, performing filtering processing on the voltage and current data to obtain feature voltage and current data, obtaining feature energy data of the feature voltage and current data within a pre-set observation time window, only when the feature energy data is greater than the first threshold, judging that the voltage and current data is reliable, and according to the feature voltage and current data, calculating a measured resistance value of the loudspeaker, and respectively comparing the measured resistance value with a lower threshold and an upper threshold to detect an operating state of a load of the loudspeaker; otherwise, the voltage and current data is judged to be unreliable, and resetting the obtained voltage and current data; thus, it is possible to detect whether there is a short-circuit fault or an open-circuit fault in the loudspeaker load without adding an additional output signal, while taking into account the flexibility and intuition in the threshold configuration.

Finally, it should be noted that: the above embodiments are only used to illustrate the technical solution of the present invention, and not to limit the same; while the present invention has been described in detail and referring to the foregoing embodiments, it will be understood by a person skilled in the art that: the technical solutions described in the foregoing embodiments may still be modified, or some or all of the technical features may be equivalently replaced; and these modifications or substitutions do not depart from the spirit of the corresponding technical solutions of the embodiments of the present invention.

1. A loudspeaker load diagnosis method, wherein a first terminal and a second terminal of the loudspeaker are respectively coupled to a first terminal and a second terminal of an amplifier; the method comprising:
obtaining voltage and current data output by the first terminal and the second terminal of the amplifier;
performing filtering processing on the voltage and current data to obtain feature voltage and current data, wherein the voltage and current data comprises a first voltage and a first current output by the first terminal of the amplifier, and a second voltage and a second current output by the second terminal of the amplifier; the feature voltage and current data comprises a first feature voltage corresponding to the first voltage, a first feature current corresponding to the first current, a second feature voltage corresponding to the second voltage and a second feature current corresponding to the second current;
calculating a measured resistance value of the loudspeaker based on the feature voltage and current data;
obtaining feature energy data of the feature voltage and current data within a pre-set observation time window, specifically comprising:
extracting amplitude, energy or decibels of the first feature voltage, the first feature current, the second feature voltage and the second feature current within the pre-set observation time window;
judging whether the voltage and current data is reliable based on the feature energy data; wherein the voltage and current data is judged to be reliable only if the feature energy data is greater than a first threshold; otherwise, the voltage and current data is judged to be unreliable; specifically comprising:
within the pre-set observation time window, if the time when the first feature voltage and the second feature voltage exceed a set voltage value exceeds the first threshold, judging that the voltage and current data is reliable;
otherwise, the voltage and current data is judged to be unreliable;
wherein
if the voltage and current data is reliable, performing the following steps:
comparing the measured resistance value with a lower threshold and an upper threshold respectively, detecting an operating state of a loudspeaker load, and outputting a detection result, wherein the operating state comprises a short-circuit state, an open-circuit state and a normal operating state, specifically comprising:
comparing the measured resistance value with a lower threshold and an upper threshold respectively, detecting an operating state of a loudspeaker load, and outputting a detection result;
comparing the measured resistance value with a lower threshold and an upper threshold respectively, and if the measured resistance value is less than the lower threshold, judging that the loudspeaker is in a short-circuit state;
if the measured resistance value is greater than the lower threshold and less than the upper threshold, judging that the loudspeaker is in a normal operating state;
if the measured resistance value is greater than the upper threshold, judging that the loudspeaker is in an open-circuit state; and
if the voltage and current data is unreliable, performing the following steps:
resetting the obtained voltage and current data.

2. The loudspeaker load diagnosis method according to claim 1, wherein a formula for calculating a measured resistance value of the loudspeaker based on the feature voltage and current data is as follows:
$${R}_{estimate} = \frac{\sum \vert {V}_{feature} \vert}{\sum \vert {I}_{feature} \vert}$$
wherein Rₑₛₜᵢₘₐₜₑ is a measured resistance value of the loudspeaker, V_{feature} is a differential voltage value, and I_{feature} is a current feature value; wherein the differential voltage value is a difference between the first feature voltage and the second feature voltage, and the current feature value is a smaller value between the first feature current and the second feature current.

3. The loudspeaker load diagnosis method according to claim 1, wherein a formula for calculating a measured resistance value of the loudspeaker based on the feature voltage and current data is as follows:
$${R}_{estimate} = \frac{\sqrt{\sum {( {V}_{feature} )}^{2}}}{\sqrt{\sum {( {I}_{feature} )}^{2}}}$$
wherein Rₑₛₜᵢₘₐₜₑ is a measured resistance value of the loudspeaker, V_{feature} is a differential voltage value, and I_{feature} is a current feature value; wherein the differential voltage value is a difference between the first feature voltage and the second feature voltage, and the current feature value is a smaller value between the first feature current and the second feature current.

4. The loudspeaker load diagnosis method according to claim 1, wherein a formula for calculating a measured resistance value of the loudspeaker based on the feature voltage and current data is as follows:
$${R}_{estimate} = db 2 linear ( linear 2 db ( \sum ( {V}_{feature} ) ) - linear 2 db ( \sum {( {I}_{feature} )}^{2} ) )$$
wherein Rₑₛₜᵢₘₐₜₑ is a measured resistance value of the loudspeaker, V_{feature} is a differential voltage value, and I_{feature} is a current feature value; wherein the differential voltage value is a difference between the first feature voltage and the second feature voltage, and the current feature value is a smaller value between the first feature current and the second feature current.

5. A loudspeaker load diagnosis system for performing the method according to claim 4, comprising:
an amplifier;
a loudspeaker having a first terminal and a second terminal respectively coupled to a first terminal and a second terminal of an amplifier;
a voltage and current data acquisition module configured to obtain voltage and current data output by the first terminal and the second terminal of the amplifier;
a feature voltage and current data acquisition module configured to perform filtering processing on the voltage and current data to obtain feature voltage and current data;
a measured resistance value acquisition module configured to calculate a measured resistance value of the loudspeaker based on the feature voltage and current data;
a feature energy data acquisition module configured to obtain feature energy data of the feature voltage and current data within a pre-set observation time window;
a data reliability judgment module configured to judge whether the voltage and current data is reliable based on the feature energy data; wherein the voltage and current data is judged to be reliable only if the feature energy data is greater than a first threshold; otherwise, the voltage and current data is judged to be unreliable;
a detection module configured to,
if the voltage and current data is reliable, perform the following steps:
compare the measured resistance value with a lower threshold and an upper threshold respectively, detect an operating state of a loudspeaker load, and output a detection result;
if the voltage and current data is unreliable, perform the following steps:
reset the obtained voltage and current data.

6. The loudspeaker load diagnosis system according to claim 5, further comprising a DAC module;
wherein an input end of the DAC module receives an audio digital signal, and an output end thereof is coupled to an input end of the amplifier to output a voltage control signal, the voltage control signal comprising voltage data output by the first terminal and the second terminal of the amplifier.

7. The loudspeaker load diagnosis system according to claim 6, wherein the voltage and current data acquisition module is configured to
obtain current data output by the first terminal and second terminal of the amplifier and obtain voltage data output by the first terminal and second terminal of the amplifier based on the voltage control signal.

8. An electronic device, comprising a memory, a processor and a program stored on the memory and executable on the processor, wherein the processor, when executing the program, implements the steps of the method according to claim 4.

9. A computer-readable storage medium having stored thereon a computer program, wherein the computer program, when executed by a processor, implements the steps of the method according to claim 4.

10. A computer-readable storage medium having stored thereon a computer program, wherein the computer program, when executed by a processor, implements the steps of the method according to claim 3.

11. A computer-readable storage medium having stored thereon a computer program, wherein the computer program, when executed by a processor, implements the steps of the method according to claim 2.

12. A computer-readable storage medium having stored thereon a computer program, wherein the computer program, when executed by a processor, implements the steps of the method according to claim 1.

13. An electronic device, comprising a memory, a processor and a program stored on the memory and executable on the processor, wherein the processor, when executing the program, implements the steps of the method according to claim 3.

14. An electronic device, comprising a memory, a processor and a program stored on the memory and executable on the processor, wherein the processor, when executing the program, implements the steps of the method according to claim 2.

15. An electronic device, comprising a memory, a processor and a program stored on the memory and executable on the processor, wherein the processor, when executing the program, implements the steps of the method according to claim 1.

16. A loudspeaker load diagnosis system for performing the method according to claim 3, comprising:
an amplifier;
a loudspeaker having a first terminal and a second terminal respectively coupled to a first terminal and a second terminal of an amplifier;
a voltage and current data acquisition module configured to obtain voltage and current data output by the first terminal and the second terminal of the amplifier;
a feature voltage and current data acquisition module configured to perform filtering processing on the voltage and current data to obtain feature voltage and current data;
a measured resistance value acquisition module configured to calculate a measured resistance value of the loudspeaker based on the feature voltage and current data;
a feature energy data acquisition module configured to obtain feature energy data of the feature voltage and current data within a pre-set observation time window;
a data reliability judgment module configured to judge whether the voltage and current data is reliable based on the feature energy data; wherein the voltage and current data is judged to be reliable only if the feature energy data is greater than a first threshold; otherwise, the voltage and current data is judged to be unreliable;
a detection module configured to,
if the voltage and current data is reliable, perform the following steps:
compare the measured resistance value with a lower threshold and an upper threshold respectively, detect an operating state of a loudspeaker load, and output a detection result;
if the voltage and current data is unreliable, perform the following steps:
reset the obtained voltage and current data.

17. The loudspeaker load diagnosis system according to claim 16, further comprising a DAC module;
wherein an input end of the DAC module receives an audio digital signal, and an output end thereof is coupled to an input end of the amplifier to output a voltage control signal, the voltage control signal comprising voltage data output by the first terminal and the second terminal of the amplifier.

18. The loudspeaker load diagnosis system according to claim 17, wherein the voltage and current data acquisition module is configured to
obtain current data output by the first terminal and second terminal of the amplifier and obtain voltage data output by the first terminal and second terminal of the amplifier based on the voltage control signal.

19. A loudspeaker load diagnosis system for performing the method according to claim 1, comprising:
an amplifier;
a loudspeaker having a first terminal and a second terminal respectively coupled to a first terminal and a second terminal of an amplifier;
a voltage and current data acquisition module configured to obtain voltage and current data output by the first terminal and the second terminal of the amplifier;
a feature voltage and current data acquisition module configured to perform filtering processing on the voltage and current data to obtain feature voltage and current data;
a measured resistance value acquisition module configured to calculate a measured resistance value of the loudspeaker based on the feature voltage and current data;
a feature energy data acquisition module configured to obtain feature energy data of the feature voltage and current data within a pre-set observation time window;
a data reliability judgment module configured to judge whether the voltage and current data is reliable based on the feature energy data; wherein the voltage and current data is judged to be reliable only if the feature energy data is greater than a first threshold; otherwise, the voltage and current data is judged to be unreliable;
a detection module configured to,
if the voltage and current data is reliable, perform the following steps:
compare the measured resistance value with a lower threshold and an upper threshold respectively, detect an operating state of a loudspeaker load, and output a detection result;
if the voltage and current data is unreliable, perform the following steps:
reset the obtained voltage and current data.

20. The loudspeaker load diagnosis system according to claim 19, further comprising a DAC module;
wherein an input end of the DAC module receives an audio digital signal, and an output end thereof is coupled to an input end of the amplifier to output a voltage control signal, the voltage control signal comprising voltage data output by the first terminal and the second terminal of the amplifier.
